(19) United States
(12) Patent Application Publication
(10) Pub. No.: US 2009/0025708 A1
(43) Pub. Date: Jan. 29, 2009

(54) Rolling Motion Tracking Solar Assembly

(75) Inventor: Jefferson G. Shingleton, Auburn, NY (US)

Correspondence Address: SunPower Corporation c/o;Haynes Beffel & Wolfeld LLP, P.O. Box 366, Half Moon Bay, CA, 94019, US

(73) Assignee: SunPower Corporation, San Jose, CA (US)

(21) Appl. No.: 12/178,525

(22) Filed: Jul. 23, 2008

Related U.S. Application Data
(60) Provisional application No. 60/951,548, filed on Jul. 24, 2007.

(51) Int. Cl. F24J 2/38; H01L 31/042

(52) U.S. Cl. 126/600; 136/246

(57) ABSTRACT

A tracking solar assembly includes a base, a first support and a second support. A solar panel is mountable the base. The first support may comprise a first curved, rolling surface fixed relative to the base. The first and second supports are engageable with the support surface. The first curved surface can be rolled along the support surface to move the base between first and second orientations. The base and any solar panel may have sufficient weight to be inherently stable and resist wind loads without being secured to the support surface. The invention may comprise means for biasing the base to a chosen orientation at or between the first orientation and the second orientation. The upper surface of the base may have open regions extending into the base with solar panels mounted within the open regions with the open regions acting as solar concentrators for the solar panels.

### CROSS-REFERENCE TO OTHER APPLICATIONS

This application claims the benefit of U.S. provisional patent application No. 60/951,548 filed 24 Jul. 2007.

### FEDERALLY SPONSORED RESEARCH OR DEVELOPMENT

This invention was made with government support under NREL Subcontract No. ZAX-6-33628-09 awarded by the Department of Energy. The government has certain rights in this invention.

### BACKGROUND OF THE INVENTION

Photovoltaic arrays are used for a variety of purposes, including as a utility interactive power system, a power supply for a remote or unmanned site, a cellular phone switch-site power supply, or a village power supply. These arrays can have a capacity from a few kilowatts to a hundred kilowatts or more, and are typically installed where there is a reasonably flat area with exposure to the sun for significant portions of the day.

In general terms, tracking solar collector systems have their solar panels, typically photovoltaic panels, in the form of rows supported on a torque tube that serves as an axis. A tracker drive system may be used to rotate or rock the rows about their tilt axes to keep the panels as square to the sun as possible. Usually, the rows are arranged with their axes disposed in a north-south direction, and the trackers gradually rotate the rows of panels throughout the day from an east-facing direction in the morning to a west-facing direction in the afternoon. The rows of panels are brought back to the east-facing orientation for the next day. One solar collector arrangement of this type is shown in Barker et al. U.S. Pat. No. 5,228,924. In this arrangement, each row of panels has its own drive mechanism. Other designs, such as that shown in U.S. Pat. No. 6,058,930, employ a single actuator to control multiple rows of solar panels.

Air moving across an array of photovoltaic (PV) or other solar collector assemblies mounted to the roof of a building, or other support surface, creates two types of forces on the PV assemblies: a lateral force tending to push the PV assemblies sideways and a wind uplift force tending to lift the PV assemblies. Much work has been done in the design and evaluation of arrays of PV assemblies to minimize wind forces. See U.S. Pat. Nos. 5,316,592; 5,505,788; 5,746,839; 6,061,978; 6,148,570; 6,495,750; 6,534,703; 6,501,013 and 6,570,084.

### BRIEF SUMMARY OF THE INVENTION

A first example of a tracking solar assembly, for use with a support surface, includes a base, a first support and a second support. A solar panel can be mounted to and supported by the base. The first support comprises a first curved, rolling surface fixed relative to the base. The first and second supports are engageable with the support surface. The first curved surface can be rolled along the support surface to move the base between first and second orientations. In some examples the base and any solar panel therewith has sufficient weight to be inherently stable and resist wind loads without securing the tracking solar assembly to the support surface. In some examples the tracking solar assembly has a weight and a center of gravity; the weight of the tracking solar assembly acts as a restoring force by virtue of the center of gravity becoming vertically misaligned with the pivot axis during said movement between the generally east-facing and generally west-facing orientations, such misalignment tending to cause the tracking solar assembly to move towards an equilibrium position with the center of gravity generally directly vertically aligned with the pivot axis. In some examples of the invention further comprises means for at least periodically moving the base during a daylight period from the first orientation to the second orientation, the first and second orientations being generally east-facing and generally west-facing orientations respectively. In some examples of the invention further comprises means for biasing the base to a chosen orientation at or between the first orientation and the second orientation, the first and second orientations being generally east-facing and generally west-facing orientations respectively. In some examples the base comprises an upper surface and open regions extending into the base from the upper surface; the solar panels can be mounted within the open regions spaced apart from the upper surface with the open regions acting as solar concentrators for the solar panels.

A second example of a tracking solar assembly, for use with a support surface, comprises a support assembly comprising a base and a base support. A solar panel is mounted to and supported by the base. The base support is placeable on the support surface without securement thereto so to support the base for movement of the base between first and second orientations. The base and the solar panel therewith have sufficient weight to be inherently stable and resist wind loads without securing the support assembly to the support surface.

A third example of a tracking solar assembly comprises a support surface and a support assembly. The support assembly comprises a base, a first support and a second support. A solar panel can be mounted to and supported by the base. The first support is supportable by the support surface at a fixed position on the support surface. The first support comprises a first curved, rolling surface supporting and engaging the base. The first curved, rolling surface is fixed relative to the support surface. The second support is engageable with the support surface. The base is movable between first and second orientations as the first curved, rolling surface engages and rolls along the base.

Other features, aspects and advantages of the present invention can be seen on review the figures, the detailed description, and the claims which follow.

### BRIEF DESCRIPTION OF THE DRAWINGS

FIG. 1 is an overall view of an example of a tracking solar assembly viewed from the underside of the base;

FIG. 2 is a partially exploded view of the assembly of FIG. 1 showing one solar panel spaced apart from the base;

FIG. 3 is a top plan view of the assembly of FIG. 1;

FIG. 4 is a side elevation will view of the assembly of FIG. 1 showing a drive line and a pulley connected to the base;

FIG. 5 is a bottom plan view of the assembly of FIG. 4 showing the morning, noon and evening pivot axes shown in dashed lines;

FIG. 6 is a simplified top plan view of a row of the tracking solar assemblies of FIG. 4 at a noontime orientation;

FIG. 7 is a simplified side, South-facing view of the row of solar assemblies of FIG. 6 at the noontime orientation;

FIG. 8 shows the rover of solar assemblies of FIG. 7 in a morning, East-facing orientation;

FIGS. 9 and 10 are side and bottom plan views of a tracking solar assembly similar to that of FIG. 1 but including a linear weight drive used to change the center of gravity and thus change the East-West orientation to permit the assembly to follow the sun from morning to evening;

FIGS. 11 and 12 illustrate an alternative to the assembly of FIGS. 9 and 10 in which the center of gravity is changed using a pendulum type of driver;

FIGS. 13 and 14 show another alternative to the assembly of FIGS. 9 and 10 in which the center of gravity is changed using a liquid ballast assembly;

FIG. 15 is a top use similar to that of FIG. 3 but in which the lateral edges are not parallel but converge as they extend from the equatorial edge and towards the polar edge;

FIG. 16 illustrates a further example using an extension at the polar edge, the extension having a curved outer edge acting as the curved rolling support;

FIG. 17 shows an example summer to that of FIG. 16 but including both the polar edge extension of FIG. 16 and an equatorial edge extension, the curved, rolling surfaces of the extensions riding within tracks;

FIGS. 18 in 19 are top and side views showing example of a quasi-stable tracking solar assembly;

FIG. 19A is a side view of an alternative to the quasi-stable tracking solar assembly of FIGS. 18 and 19;

FIG. 20 is a partially exploded view of an alternative to the example of FIGS. 1-5 with open regions formed in the base beneath the solar panels;

FIGS. 21 and 22 are bottom and top partially exploded views of a further alternative to the example of FIGS. 1-5 in which the base has solar-concentrating open areas for each of the reduced-size solar panels; and

FIGS. 23-25 and show still further examples of the tracking solar assembly in which the first support is a component separate and apart from the base.

### DETAILED DESCRIPTION OF THE INVENTION

The following description will typically be with reference to specific structural embodiments and methods. It is to be understood that there is no intention to limit the invention to the specifically disclosed embodiments and methods but that the invention may be practiced using other features, elements, methods and embodiments. Preferred embodiments are described to illustrate the present invention, not to limit its scope, which is defined by the claims. Those of ordinary skill in the art will recognize a variety of equivalent variations on the description that follows. Like elements in various embodiments are commonly referred to with like reference numerals.

This invention relates to solar energy collection, and in particular to a rolling motion tracking solar assembly which can track the motion of the sun relative to the earth. The invention is more particularly directed to improvements in structure which provides inherent stability to effectively prevent wind loads from damaging the tracking solar assemblies. The invention applies to solar assemblies in which the solar panels include arrays of photovoltaic cells for generating electrical power, but the same principles can be applied to arrangements for solar heating, for example.

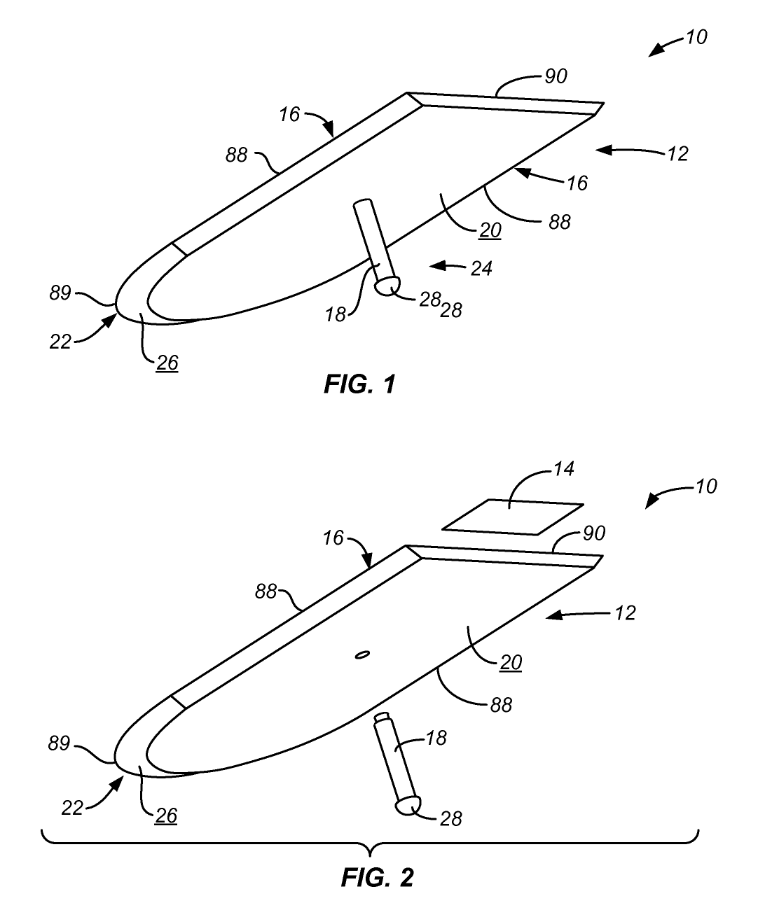

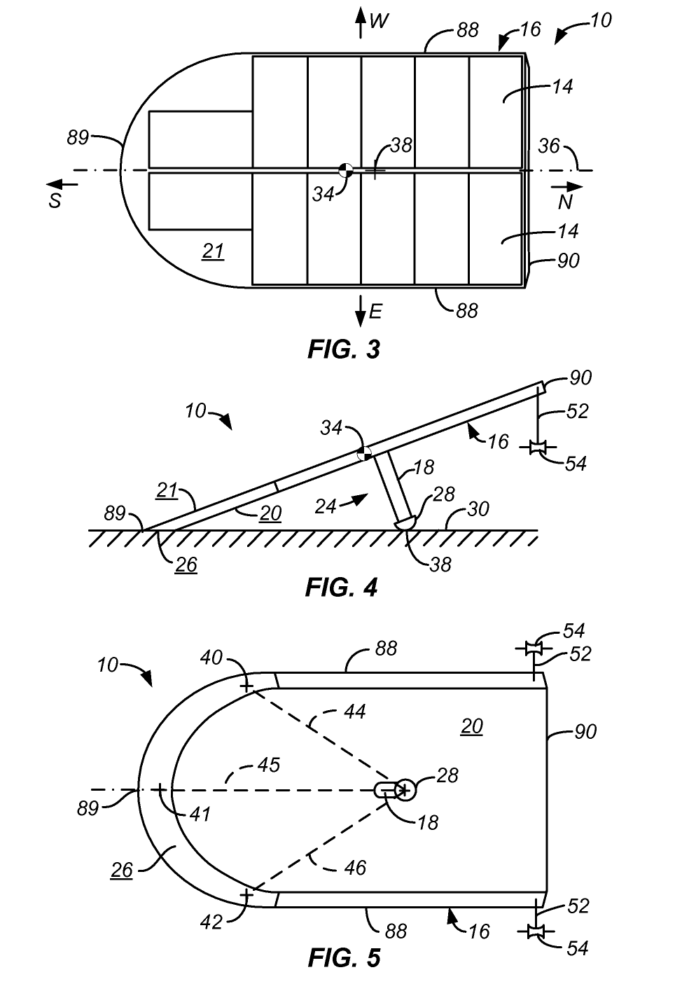

FIGS. 1-5 are several views of one example of a rolling motion tracking solar assembly 10 comprising broadly a solar panel support assembly 12 and at least one solar panel 14. Although a single solar panel 14 could be used with assembly 10, multiple solar panels 14 are shown in the various examples. Solar panel support assembly 12 includes a base 16 and a support leg 18 rigidly attached to and extending from the lower surface 20 of base 16. Solar panels 14 are mounted to the upper surface 21 of base 16. Support assembly 12 includes a first support 22 and a second support 24.

One aspect of the invention is the recognition that if one were to make assembly 10 out of a relatively inexpensive but heavy material, such as reinforced concrete, the assembly could inherently resist wind loads. Accordingly, base 16 is preferably made of reinforced concrete or some other heavy material. Doing so makes assembly 10 inherently stable to thus resist movement due to wind loads without securing assembly 10 to support surface 30. For example, a base 16 having an upper surface 21 with a surface area of 160 square feet (14.9 square meters) may have the weight of about 4000 to 6000 pounds. The choice of weight to surface area will depend primarily on site conditions including the range of angular orientations, the shape of base 16 and expected wind speeds. If the wind speed were large enough to cause assembly 10 to pivot to a maximum east-facing or West-facing orientation, the weight of assembly 10 can be sufficient to prevent any further movement. That is, it is highly unlikely that under normal circumstances wind alone would be sufficient to flip assembly 10 over or otherwise move the assembly from its desired location.

In the example of FIGS. 1-5, first support 22 comprises a first curved, rolling surface 26 formed along one end of base 16, while second support 24 comprises support leg 18 with a second curved, rolling support 28 at the distal end of support leg 18. In other examples instead of rolling support 28, a joint could be used at either end of support leg 18 or along the length of support leg 18. As shown in FIG. 4, rolling surface 26 and rolling support 28 are both supported by a support surface 30. Surface 30 will typically include prepared areas for contact with rolling surface 26 and rolling support 28. For example, a strip of compacted gravel or concrete may be used to support rolling surface 26 while rolling support 28 could be supported by a concave bearing surface, such as a semi-spherical stainless steel cup supported within a concrete block or by a strip pad of compacted gravel.

One example of the FIGS. 1-5 solar assembly 10 has a centrally located center of gravity 34. Base 16 will typically be oriented with its longitudinal centerline 36 oriented on a polar axis. In the Northern Hemisphere rolling surface 26 is oriented towards the south while in the Southern Hemisphere rolling surface 26 is oriented to the north. For the purposes of discussion, the examples will be described as used in the Northern Hemisphere.

Solar assembly 10 defines a moving instantaneous pivot axis. The instantaneous pivot axis extends from North pivot point 38, where rolling support 28 contacts support surface 30, and the location along first curved, rolling surface 26 which rests against support surface 30. Three such locations are identified in FIGS. 2 and 5 as the morning South pivot point 40, the noon South pivot point 41 and the evening South pivot point 42 to define the morning pivot axis 44, the noon pivot axis 45 and the evening pivot axis 46.

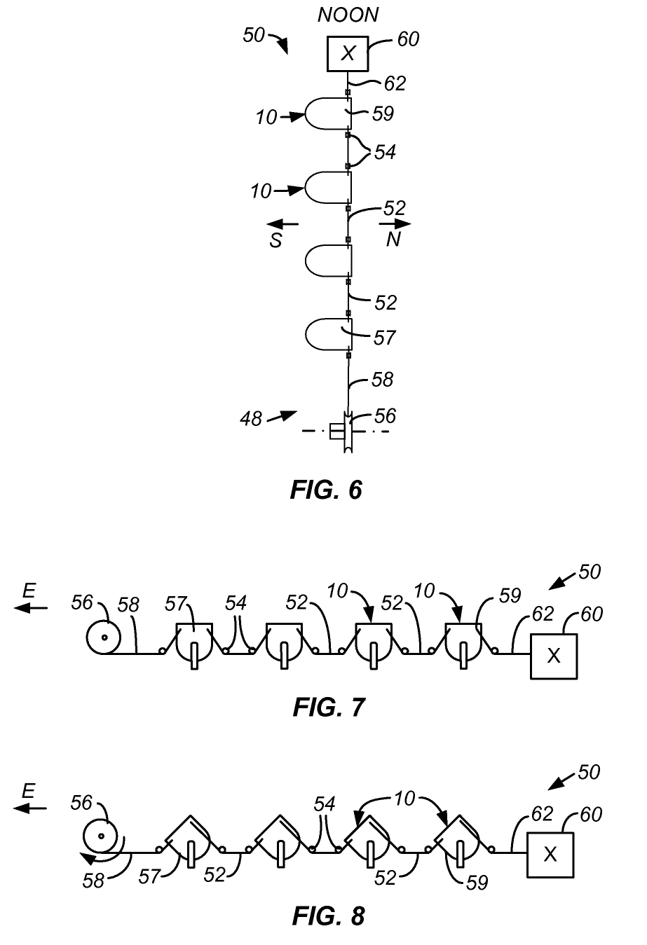

Assembly 10 is moved between the morning orientation, at which morning South pivot point 40 is contacting support surface 30, and evening South pivot point 42 by a drive assembly 48, an example of which is shown in simplified form in FIG. 6 and 7. FIGS. 6 and 7 illustrate a row 50 of solar assemblies 10 all being driven simultaneously by drive assembly 48. Drive assembly 48 includes drive lines 52 which engage guide pulleys 54 and connect adjacent solar assemblies 10 to one another. Drive assembly 48 also includes a driver 56 connected to a tracking solar assembly 57 at one end of a row 50 by a driver drive line 58. The tracking solar assembly 59 at the opposite end of row 50 is, in some examples, connected to a tension source 60, such as a spring, counterweight, et cetera, by a tension source drive line 62.

Without any tension on any of the drive lines 52, 58, 62, each assembly 10 would tend to orient itself with center of gravity 34 vertically aligned with the pivot axis. As shown in FIG. 5, when a center of gravity 34 is aligned with centerline 36, this occurs when solar assembly 10 is it a noontime orientation with noon south pivot point 41 resting on support surface 30. When assembly 10 is tilted one way or the other, that is towards its evening orientation or its morning orientation, a restoring force is created by virtue of the misalignment of center of gravity 34 with the instantaneous pivot axis. To move assemblies 10 of row 50 to the morning orientation, driver 56 pulls on driver drive line 58 thus causing the row of assemblies tend to simultaneously become oriented into the morning, east-facing orientation as shown in FIG. 8. In doing so driver 56 typically overcomes both the restoring force created by the weight of each assembly 10 and the force exerted by tension source 62. Movement of row 50 of assemblies 10 from the morning orientation of FIG. 8 towards an evening orientation, not shown, is caused by tension source 60 pulling on tension source drive line 62 and by the appropriate release of driver drive line 58 from driver 56 as the day progresses from morning to evening. In other examples driver 56 and tension source 60 can be reversed with driver 56 at the west end of row 50 and tension source 60 at the east end. Assuming tension source 60 does not require a power source, such an arrangement will allow row 50 of assemblies 10 to naturally return to their East facing orientations at the end of the day without the application of power to driver 56. In other examples tension source 60 may be a powered driver so that the amount of force exerted by tension source 60 on tension source drive line 62 can be controlled.

In some situations it may be desired to have the center of gravity be aligned with the instantaneous pivot axis at other than noontime, such as when in the morning orientation. In such case weight can be added to, for example, lower surface 20 so that the center of gravity is aligned with morning pivot axis 44, or, the center of gravity could be modified by altering the geometry of the base 16 or the position of support leg 18. With driver 56 at the west end of row 50, this may eliminate the need for tension source 60, or at least reduce the amount of force that must be exerted by tension source 60.

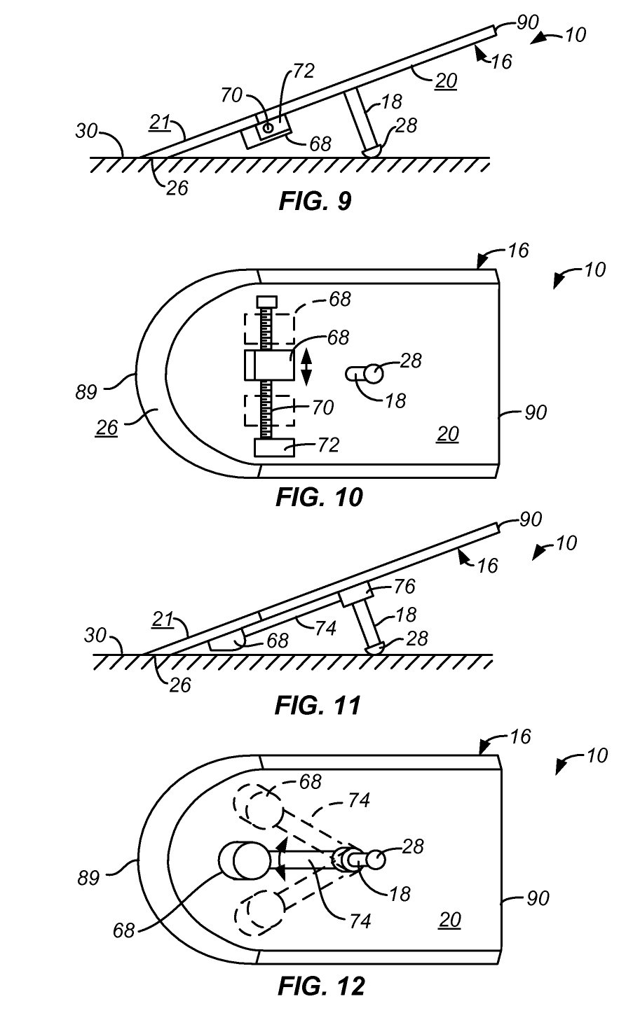

At times it may be desired to have each assembly 10 be individually driven. For example, in some situations it may not be desired, or it may not be possible, to drive an entire row 50 of assemblies 10. FIGS. 9-14 illustrate three examples of individually driven assemblies 10 by shifting the center of gravity of the assembly throughout day. FIGS. 9 and 10 illustrate a linear weight drive 66 mounted to lower surface 20 of assembly 10. Drive 66 includes a weight 68 threadably mounted to an East-West oriented threaded shaft or worm 70. Worm 70 is rotated by a worm drive 72 causing weight 68 to move laterally, that is an East-West direction. This causes assembly 10 to orient itself in the proper orientation for the maximum solar exposure. The control of worm drive can be by a variety of conventional or unconventional manners. For example, control can be preprogrammed into worm drive 72 based on the time of day. Appropriate sun tracking devices can be used to control the operation of worm drive 72. A separate tracking device can be associated with each assembly 10 or a common tracking device can be used with information provided to each worm drive 72 through wires or wireless connections. The power to drive worm drives 72 can be obtained from solar panels 14. One solar panel 14 of each assembly 10 may be dedicated to powering worm drive 72.

FIGS. 11 and 12 show another example of an individually driven solar assembly 10. The example of FIGS. 11 and 12 is a pendulum type in which weight 68 is mounted to one end of an arm 74. The other end of arm 74 is connected to a pendulum driver 76 secured to support leg 18 adjacent to lower surface 20. As indicated in FIG. 12, actuation of pendulum driver 76 causes arm 74 to rotate over a predetermined arc length thus moving weight 68 and changing the location of the center of gravity 34 tracking solar assembly 10. As with the example of FIGS. 9 and 10, this causes rolling surface 26 to roll along support surface 30 to permit assembly 10 to follow the movement of the sun during the day.

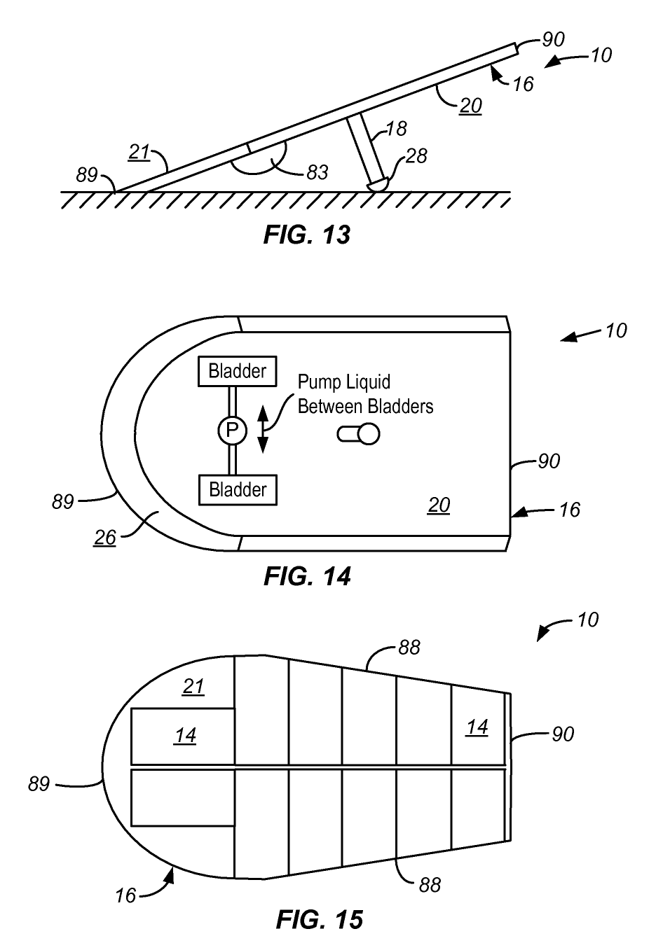

FIG. 13 and 14 illustrate a still further example of an individually driven solar assembly 10. In this example a liquid ballast assembly 80 is secured to lower surface 20 and includes first and second bladders 82, 83, or other liquid containers, spaced apart from one another in an East-West orientation. Bladders 82, 83 are connected by a liquid line 84 which has a pump 86 situated along line 84. Pumping liquid back and forth between bladders 82, 83 changes the location of the center of gravity of assembly 10 thus permitting assembly 10 to track the movement of the sun from a morning orientation to an evening orientation.

In the examples of FIGS. 1-14, base 16 includes rolling surface 26 along equatorial edge 89 and parallel lateral edges 88 extending from edge 89 to polar edge 90. In the example of FIG. 15, lateral edges 88 are not parallel but start to converge as they extend away from equatorial edge 89 and towards polar edge 90. This configuration provides several primary differences relative to the examples of FIGS. 1-14. First, the maximum tilted orientation to the east or west can be greater with the example of FIG. 15 because of the converging lateral edges 88. Second, the surface area towards polar edge 90 is less with the FIG. 15 example than with the earlier examples to help reduce wind resistance. Third, in this case the assembly can be configured to point to the NE in the morning and the NW in the afternoon, to improve the summer energy productivity.

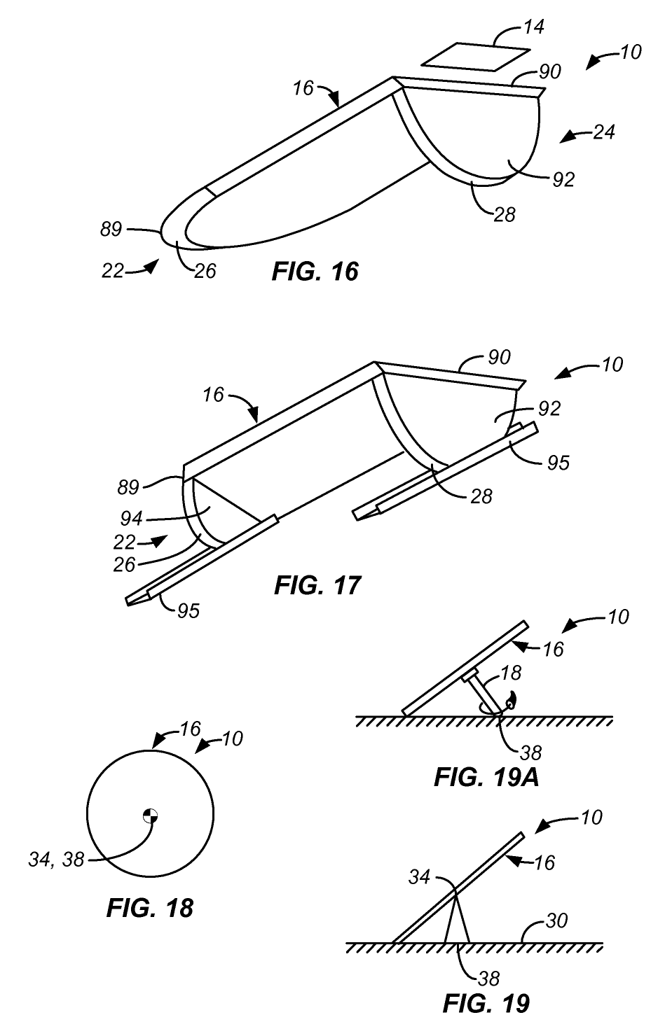

FIG. 16 illustrates a further example in which second support 24 comprises a polar end body extension 92 along polar edge 90. Body extension 92 has an outer curved edge acting as second, curved rolling support 28. Rolling support 28 extends between lateral edges 88. The FIG. 17 example is similar to the FIG. 16 example in that it includes a polar end body extension 92; however, first support 22 comprises an equatorial end body extension 94. Body extension 94 has an outer curved edge acting as first curved, rolling surface 26. Assemblies including body extensions 92, 94 might be useful when the assemblies are mounted on a roof, in such situations the curved outer edges of extensions 92, 94 may roll within or on tracks 95 as illustrated in FIG. 17 to help protect the roof surface and distribute the weight on the roof surface. Also, any of the driven solar assemblies could be envisioned as a fixed-tilt (non-tracking) solar assembly but which might in high winds be caused to roll into a position that has lower wind loads than in the normal position.

FIGS. 18 and 19 illustrate an example of an assembly 10 in which base 16 is circular with a center of gravity 34 aligned with North pivot point 38 so that the pivot axis always passes through the center of gravity. This permits assembly 10 to be quasi-stable at any orientation. This configuration would reduce the amount of force necessary to tilt base 16. FIG. 19A illustrates an alternative embodiment of assembly 10 of FIGS. 18 and 19. Assembly 10 of FIG. 19A is also quasi-stable and has a support leg 18 fixed to and extending from base 16.

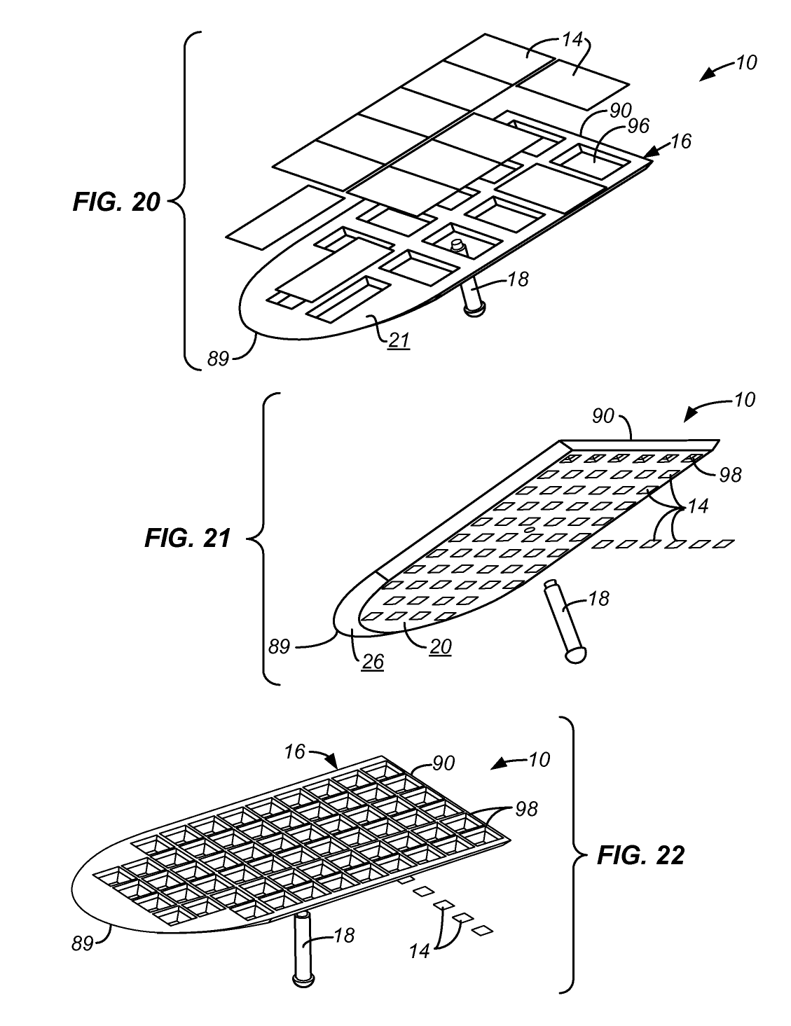

FIG. 20 illustrates an alternative to the example of FIGS. 1-5. Assembly 10 of FIG. 20 has open regions 96 extending from upper surface 21 of base 16. Base 16 is typically made of concrete. Open regions 96 extend completely through base 16 in this example. Open regions 96 are sized and located to permit solar panels 14 to be mounted on upper surface 21 and overlie the open regions. This helps to keep solar panels 14 cool by allowing cooling air currents to contact the upper and lower surfaces of solar panels 14.

FIGS. 21 and 22 illustrate a further example in which base 16 has numerous solar-concentrating open regions 98 extending completely through base 16. Solar panels 14 are mounted at the bottom of open regions 98, typically by being secured directly to lower surface 20 of base 16. The sidewalls defining open regions 98 are configured to direct solar radiation onto solar panels 14 so to concentrate the solar radiation on the solar panels. As with the FIG. 20 example, air can freely circulate on both sides of solar panels 14 to help cool the solar panels and thus increase operating efficiencies. The open regions also can be used to reduce the weight of base 16 and the cost of the concrete from which it is typically made.

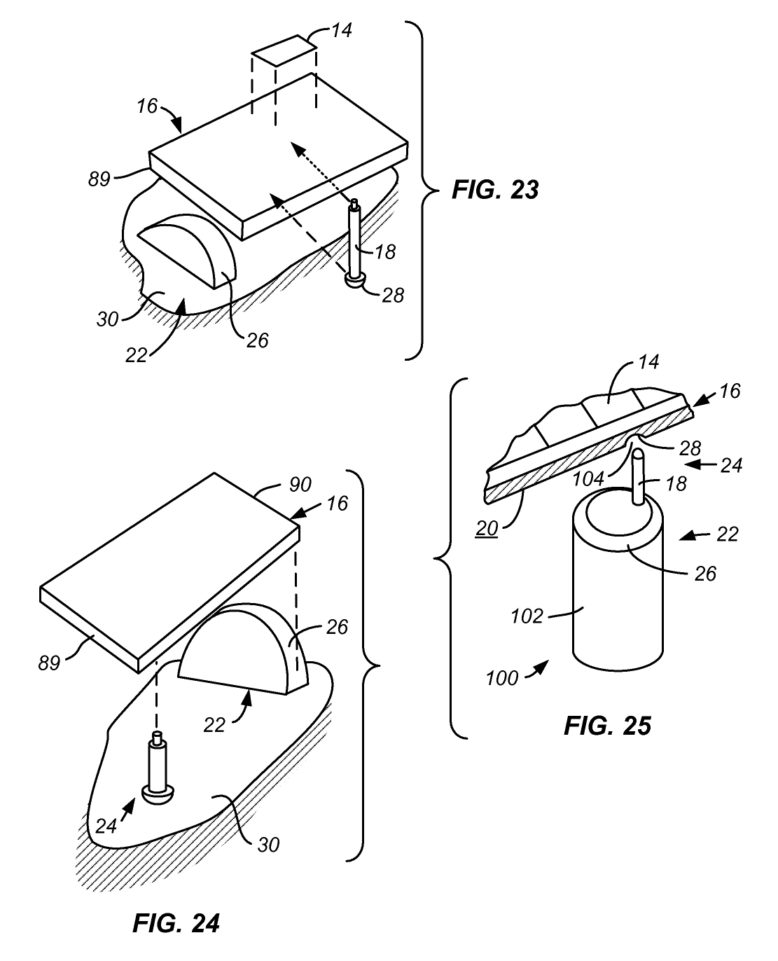

FIGS. 23-25 are directed to further examples in which a first support 22 is a component separate and apart from base 16. In the example of FIG. 23, first support 22 is supported on support surface 30 and includes first, curved rolling surface 26. Rolling surface 26 contacts lower surface 20 of base 16 along equatorial edge 89. The example of FIG. 24 switches the locations of first and second supports 22, 24 relative to the example of FIG. 23. In the example of FIG. 24, rolling surface 26 engages lower surface 20 of base 16 along polar edge 90. FIG. 25 illustrates an embodiment in which both the first and second supports 22, 24 are part of a single assembly 100. Assembly 100 includes a cylindrical base 102 having first curved, rolling surface 26 formed along its upper edge and a support leg 18 extending from its upper end. Rolling support 28 is formed at the end of support leg 18 and engages a semi-spherical opening 104 formed in lower surface 20 of base 16.

The above descriptions may have used terms such as above, below, top, bottom, over, under, et cetera. These terms may be used in the description and claims to aid understanding of the invention and not used in a limiting sense.

While the present invention is disclosed by reference to the preferred embodiments and examples detailed above, it is to be understood that these examples are intended in an illustrative rather than in a limiting sense. It is contemplated that modifications and combinations will occur to those skilled in the art, which modifications and combinations will be within the spirit of the invention and the scope of the following claims. Any and all patents, patent applications and printed publications referred to above are incorporated by reference.

What is claimed is:

1. A tracking solar assembly for use with a support surface, the assembly comprising:
a base, wherein a solar panel can be mounted to and supported by the base;
a first support and a second support;
the first support comprising a first curved, rolling surface fixed relative to the base;
wherein the first and second supports are engageable with a support surface; and
wherein the first curved surface can be rolled along the support surface to move the base between first and second orientations.

2. The assembly according to claim 1, wherein the first curved, rolling surface is generally coplanar with the base.

3. The assembly according to claim 1, wherein the first support comprises a first body extension with the first curved, rolling surface extending away from the base.

4. The assembly of claim 3, further comprising a track along which the first curved, rolling surface rolls.

5. The assembly of claim 3, wherein the second support comprises a second body extension, the second body extension comprising a second curved, rolling surface extending away from the base.

6. The assembly according to claim 1, wherein:
the first and second orientations are generally east and west facing orientations; and
the first support is a first, south support and the second support is a second, north support.

7. The assembly according to claim 1, wherein the base and any solar panel therewith has sufficient weight to be inherently stable and resist wind loads without securing the tracking solar assembly to the support surface.

8. The assembly according to claim 1, wherein the second support comprises a second curved, rolling surface.

9. The assembly according to claim 1, wherein the second support comprises an elongated support leg having an upper end at the base and a lower end at the support surface.

10. The assembly according to claim 1, wherein the base is pivotal about north and south pivot points at the first and second supports as the base moves between generally east-facing and generally west-facing orientations, the north and south pivot points defining a pivot axis.

11. The assembly according to claim 10, wherein:
the tracking solar assembly has a weight and a center of gravity; and
the weight of the tracking solar assembly acting as a restoring force by virtue of the center of gravity becoming vertically misaligned with the pivot axis during said movement between the generally east-facing and generally west-facing orientations, such misalignment tending to cause the tracking solar assembly to move towards an equilibrium position with the center of gravity generally directly vertically aligned with the pivot axis.

12. The assembly according to claim 11, wherein the tracking solar assembly is constructed so that the equilibrium position is at a selected one of the following orientations:
a noontime orientation generally halfway between the generally east-facing and west-facing orientations; and
the generally east-facing orientation.

13. The assembly according to claim 11, further comprising means for at least periodically changing the location of the center of gravity during a daylight period thereby causing movement of the tracking solar assembly from the generally east-facing orientation to the generally west-facing orientation.

14. The assembly according to claim 1, further comprising means for at least periodically moving the base during a daylight period from the first orientation to the second orientation, the first and second orientations being generally east-facing and generally west-facing orientations respectively.

15. The assembly according to claim 1, further comprising means for biasing the base to a chosen orientation at or between the first orientation and the second orientation, the first and second orientations being generally east-facing and generally west-facing orientations, respectively.

16. The assembly according to claim 1, wherein least a substantial portion of the tracking solar assembly is concrete.

17. The assembly according to claim 1, wherein the base comprises an upper surface and open regions extending into the base from the upper surface.

18. The assembly according to claim 17, further comprising a plurality of solar panels, and wherein a solar panel is mounted to the base at some or all of said open regions.

19. The assembly according to claim 18, wherein the solar panels are mounted within the open regions spaced apart from the upper surface, the open regions acting as solar concentrators for the solar panels.

20. The assembly according to claim 1, wherein the base comprises a PV performance-enhancing feature.

21. A tracking solar assembly, for use with a support surface, comprising:
a support assembly comprising a base and a base support;
a solar panel mounted to and supported by the base;
the base support being placeable on the support surface without securement thereto so to support the base for movement of the base between first and second orientations; and
the base and the solar panel therewith having sufficient weight to be inherently stable and resist wind loads without securing the support assembly to the support surface.

22. A tracking solar assembly comprising:
a support surface;
a support assembly comprising a base, a first support and a second support, wherein a solar panel can be mounted to and supported by the base;
the first support supportable by the support surface at a fixed position on the support surface, the first support comprising a first curved, rolling surface supporting and engaging the base, the first curved, rolling surface being fixed relative to the support surface;
the second support engageable with the support surface; and
wherein the base is movable between first and second orientations as the first curved, rolling surface engages and rolls along the base.
